(19) United States
(12) Patent Application Publication
(10) Pub. No.: US 2025/0323134 A1
(43) Pub. Date: Oct. 16, 2025

(54) PANEL-LEVEL GLASS BASED EMBEDDED SILICON BRIDGE PACKAGE AND METHOD OF MANUFACTURING THE SAME

(71) Applicant: SAMSUNG ELECTRONICS CO., LTD., Suwon-si (KR)

(72) Inventors: Jin YANG, San Jose, CA (US); WooPoung KIM, San Jose, CA (US)

(73) Assignee: SAMSUNG ELECTRONICS CO., LTD., Suwon-si (KR)

(21) Appl. No.: 18/758,723

(22) Filed: Jun. 28, 2024

Related U.S. Application Data
(60) Provisional application No. 63/632,284, filed on Apr. 10, 2024.

(51) Int. Cl. H01L 23/498; H01L 21/48; H01L 23/00; H01L 23/15; H01L 23/538; H01L 25/18

(52) U.S. Cl. CPC H01L 23/49833; H01L 21/4857; H01L 23/15; H01L 23/49816; H01L 23/49822; H01L 23/49838; H01L 23/5386; H01L 24/16; H01L 24/32; H01L 24/73; H01L 25/18; H01L 2224/16238; H01L 2224/32225; H01L 2224/73204; H01L 2924/1431; H01L 2924/1436; H01L 2924/1815

(57) ABSTRACT

Provided is a semiconductor package including a first redistribution layer, a second redistribution layer, a glass substrate between the first redistribution layer and the second redistribution layer, the glass substrate including a through-glass via configured to connect the first redistribution layer and the second redistribution layer, a first semiconductor chip and a second semiconductor chip on a second surface of the second redistribution layer, and a bridge chip included in the glass substrate and configured to connect the first semiconductor chip and the second semiconductor chip.

### CROSS-REFERENCE TO RELATED APPLICATION

This application is based on and claims benefit to U.S. Provisional Application No. 63/632,284 filed on Apr. 10, 2024 in the U.S. Patent and Trademark Office, the disclosure of which is incorporated herein in its entirety by reference.

### BACKGROUND

### 1. Field

Example embodiments of the present disclosure relate to a method of manufacturing a semiconductor package with a glass interposer and a bridge chip and an apparatus thereof.

### 2. Description of Related Art

According to the development of the electronics industry and the needs of users, electronic devices are becoming smaller and lighter. As the electronic devices become smaller and lighter, the semiconductor package used in the electronic devices is also becoming smaller and lighter and requires high reliability together with high performance and high capacity. According to the high performance and the high capacity of the semiconductor package, the power consumption is increasing in the semiconductor package. Accordingly, the importance of the structure of the semiconductor package for responding to the size/performance of the semiconductor package and more stably supplying power to the semiconductor package is increasing.

### SUMMARY

One or more example embodiments provide a method of manufacturing a semiconductor package with a glass interposer and a bridge chip, and an apparatus thereof.

According to an aspect of one or more embodiments, there is provided a semiconductor package including a first redistribution layer, a second redistribution layer, a glass substrate between the first redistribution layer and the second redistribution layer, the glass substrate including a through-glass via configured to connect the first redistribution layer and the second redistribution layer, a first semiconductor chip and a second semiconductor chip on a second surface of the second redistribution layer, and a bridge chip included in the glass substrate and configured to connect the first semiconductor chip and the second semiconductor chip.

According to another aspect of one or more embodiments, there is provided a method of manufacturing a semiconductor package, the method including providing a first redistribution layer including a first redistribution insulating layer, a first wiring pattern, and a first via connected to the first wiring pattern on a carrier substrate, providing a glass substrate including a through-glass via on the first redistribution layer, the glass substrate being configured to be electrically connected to the first redistribution layer, providing a bridge chip, providing a second redistribution layer including a second redistribution insulating layer, a second wiring pattern, and a second via connected to the second wiring pattern on the glass substrate and configured to be electrically connected to the glass substrate, and providing a first semiconductor chip and a second semiconductor chip on the second redistribution layer, wherein the bridge chip is configured to electrically connect the first semiconductor chip and the second semiconductor chip.

According to still another aspect of one or more embodiments, there is provided a semiconductor package including a first redistribution layer including a first redistribution insulating layer, a first wiring pattern, and a first via connected to the first wiring pattern, a second redistribution layer including second redistribution insulating layer, a second wiring pattern, and a second via connected to the second wiring pattern, a glass substrate between the first redistribution layer and the second redistribution layer, the glass substrate including a through-glass via configured to connect the first redistribution layer and the second redistribution layer, a first semiconductor chip and a second semiconductor chip on a second surface of the second redistribution layer, a bridge chip included in the glass substrate and electrically connecting the first semiconductor chip and the second semiconductor chip, the bridge chip being configured to electrically connect the first semiconductor chip and the second semiconductor chip, and an external terminal on the first redistribution layer, the external terminal being configured to connect the semiconductor package to a structure external to the semiconductor package.

### BRIEF DESCRIPTION OF DRAWINGS

The above and/or other aspects, features, and advantages of example embodiments of the disclosure will be more apparent from the following description taken in conjunction with the accompanying drawings, in which:

FIG. 1 illustrates a plan view of a panel-level glass based semiconductor package according to one or more embodiments;

FIG. 2 illustrates a cross-sectional view of the panel-level glass based semiconductor package of FIG. 1 taken along line A-A′ according to one or more embodiments;

FIG. 3A illustrates a cross-sectional view of forming a first redistribution layer in a method of manufacturing a panel-level glass based semiconductor package according to one or more embodiments;

FIG. 3B illustrates a cross-sectional view of laminating a photosensitive film in a method of manufacturing a panel-level glass based semiconductor package according to one or more embodiments;

FIG. 3C illustrates a cross-sectional view of forming a glass interposer in a method of manufacturing a panel-level glass based semiconductor package according to one or more embodiments;

FIG. 3D illustrates a cross-sectional view of forming a bridge chip in a method of manufacturing a panel-level glass based semiconductor package according to one or more embodiments;

FIGS. 3E and 3F illustrates a cross-sectional view of forming a second redistribution layer in a method of manufacturing a panel-level glass based semiconductor package according to one or more embodiments;

FIG. 3G illustrates a cross-sectional view of forming semiconductor chips in a method of manufacturing a panel-level glass based semiconductor package according to one or more embodiments;

FIG. 3H illustrates a cross-sectional view of forming a mold layer; and FIG. 3I illustrates forming external terminals in a method of manufacturing a panel-level glass based semiconductor package according to one or more embodiments;

FIG. 4 illustrates a panel-level glass based semiconductor package according to one or more other embodiments;

FIG. 5 illustrates a flowchart of a method of manufacturing a panel-level glass based semiconductor package including a bridge chip according to one or more embodiments;

FIG. 6 illustrates a semiconductor package architecture that may incorporate the semiconductor packages according to one or more embodiments; and

FIG. 7 illustrates a schematic block diagram of an electronic system according to one or more embodiments.

### DETAILED DESCRIPTION

The embodiments described herein are examples or example embodiments, and thus, the present disclosure is not limited thereto, and may be realized in various other forms. Each of the embodiments provided in the following description is not excluded from being associated with one or more features of another example or another embodiment also provided herein or not provided herein but consistent with the present disclosure. For example, even if matters described in a specific example or embodiment are not described in a different example or embodiment thereto, the matters may be understood as being related to or combined with the different example or embodiment, unless otherwise mentioned in descriptions thereof.

In addition, it should be understood that all descriptions of principles, aspects, examples, and embodiments are intended to encompass structural and functional equivalents thereof. In addition, these equivalents should be understood as including not only currently well-known equivalents but also equivalents to be developed in the future, that is, all devices invented to perform the same functions regardless of the structures thereof.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

Spatially relative terms, such as “over,” “above,” “on,” “upper,” “below,” “under,” “beneath,” “lower,” “top,” and “bottom,” and the like, may be used herein for ease of description to describe one element's relationship to another element(s) as illustrated in the figures. It will be understood that the spatially relative terms are intended to encompass different orientations of a semiconductor device in use or operation in addition to the orientation depicted in the figures. For example, if the semiconductor device in the figures is turned over, elements described as “below” or “beneath” other elements would then be oriented “above” the other elements. Thus, the term “below” can encompass both an orientation of above and below. The semiconductor device may be otherwise oriented (rotated 90 degrees or at other orientations) and the spatially relative descriptors used herein interpreted accordingly.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. Herein, when a term “same” is used to compare a dimension of two or more elements, the term may cover a “substantially same” dimension.

It will be understood that, although the terms “first,” “second,” “third,” “fourth,” etc. may be used herein to describe various elements, these elements should not be limited by these terms. These terms are only used to distinguish one element from another element. Thus, a first element discussed below could be termed a second element without departing from the teachings of the present disclosure.

It will be also understood that, even if a certain step or operation of manufacturing an apparatus or structure is described later than another step or operation, the step or operation may be performed later than the other step or operation unless the other step or operation is described as being performed after the step or operation.

Various embodiments are described herein with reference to cross-sectional illustrations that are schematic illustrations of the embodiments (and intermediate structures). As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present disclosure. Further, in the drawings, the sizes and relative sizes of layers and regions may be exaggerated for clarity.

For the sake of brevity, general elements to semiconductor devices may or may not be described in detail herein.

Due to the demand for higher performance computing, an increasing number of semiconductor chips are being included in a semiconductor package which is causing memory latency and increased warpage.

To reduce the memory latency and increased warpage, a semiconductor package according to one or more embodiments provide a semiconductor package including a glass interposer to increase structural stiffness to reduce warpage and a bridge chip included in the glass interposer to connect semiconductor chips such that the semiconductor chips may be formed closer to each other.

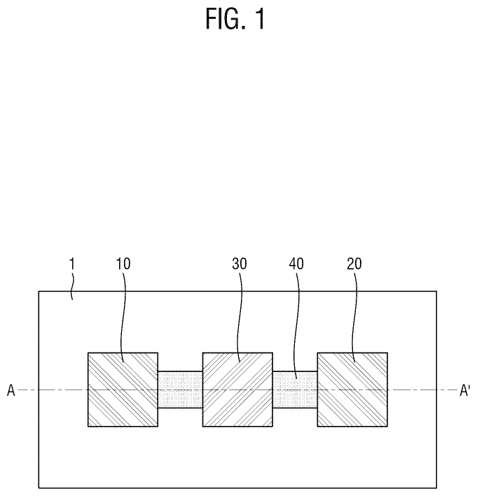

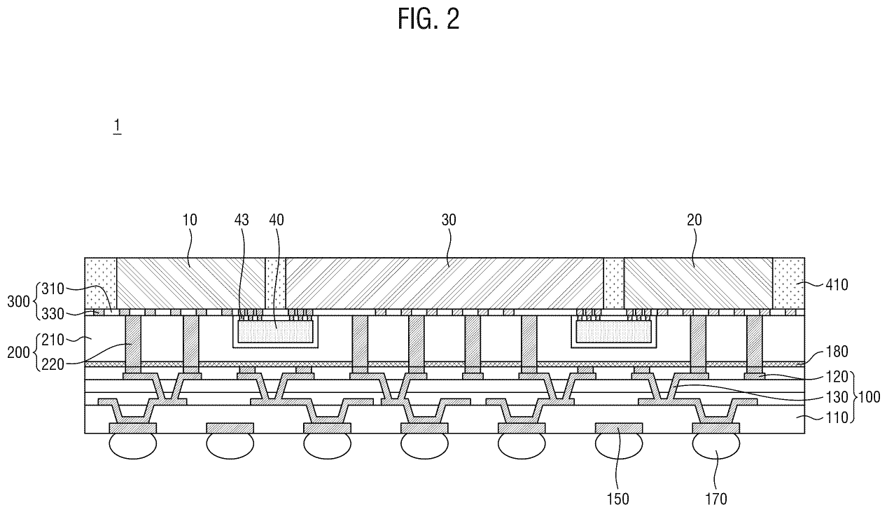

FIG. 1 illustrates a plan view of a semiconductor package according to one or more embodiments; and FIG. 2 illustrates a cross-sectional view of the semiconductor package of FIG. 1 taken along line A-A′ according to one or more embodiments.

Referring to FIGS. 1 and 2, a semiconductor package 1 may include a first semiconductor chip 10, a second semiconductor chip 20, and a third semiconductor chip 30 that may be, for example, a logic chip, a memory chip, etc., bridge chips 40 that connect semiconductor chips, a first redistribution layer 100 connecting semiconductor chips to elements external to the semiconductor package 1, a glass interposer 200 providing connection between redistribution layers, a photosensitive film 180, and a second redistribution layer 300 connecting the semiconductor chips to the glass interposer 200.

Herein, a direction parallel to a main surface (upper surface or lower surface) of the first redistribution layer 100 may be referred to as a horizontal direction (X direction and/or Y direction), and a direction perpendicular and normal to the horizontal direction (X direction and/or Y direction) may be referred to as a vertical direction (Z direction).

The semiconductor package 1 may include a package having a fan-out structure in which a size of connection layers such as a redistribution layer expands beyond the periphery of one or more semiconductor chips in the horizontal direction. A size of the first redistribution layer 100 and a size of the second redistribution layer 300 may be larger than a size of the first semiconductor chip 10, the second semiconductor chip 20, and the third semiconductor chip 30 in the horizontal direction. The size of the first redistribution layer 100 and the second redistribution layer 300 may be the same as a size of the overall semiconductor package 1 in the horizontal direction.

The first redistribution layer 100 may include first redistribution insulating layers 110, first wiring patterns 120, and first vias 130. The first redistribution insulating layers 110 may be stacked in the vertical direction (Z direction). The first redistribution insulating layer 110 may include an insulating material, such as a photo-imageable dielectric (PID) resin prepared by combining epoxy resin and photoinitiators, and may further include photosensitive polyimide and/or inorganic fillers, not being limited thereto.

The first wiring patterns 120 and the first vias 130 may conductive, and may be provided in the first redistribution insulating layer 110. The first wiring patterns 120 may be provided to extend in the horizontal direction (X direction and/or Y direction) in the first redistribution insulating layer 110. The first vias 130 may penetrate one or more first redistribution insulating layer 110 in the vertical direction (Z direction), to contact and be electrically connected with some of the first wiring patterns 120.

According to embodiments, at least some of the first wiring patterns 120 may be integrally provided together with some of the first vias 130. For example, the first wiring patterns 120 and the first vias 130, which are in contact with the upper surface of the first wiring patterns 120, may be integrally formed as a single structure.

According to embodiments, the first vias 130 may have any suitable shape including, for example, a tapered shape in which the horizontal widths of the first vias 130 decrease in the vertical direction (Z direction) away from the first semiconductor chip 10 and the second semiconductor chip 20 which may facilitate the manufacturing process.

The first wiring patterns 120 and the first vias 130 may include, for example, metals such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and an alloy thereof but is not limited thereto.

The semiconductor package 1 may further include an under bump metallurgy (UBM) layers 150. The UBM layer 150 may include a copper layer, a nickel layer, and a copper-nickel-tin intermetallic compound layer between the copper layer and the nickel layer. The UBM layers 150 may be electrically and/or physically connected to at least one of the first wiring patterns 120 and the first vias 130, and may electrically connect the first redistribution layer 100 with other components of the semiconductor package 1 such as an external connection terminals 170 that connect the semiconductor package 1 to an element external to the semiconductor package 1 such as, for example, a printed circuit board (PCB). In addition, the UBM layers 150 may prevent the external connection terminals 170 from damage such as cracking due to the thermal shock between the external connection terminals 170 and the first redistribution layer 100, to thereby improve the reliability of the semiconductor package 1. The UBM layers 150 may include a conductive material, for example, copper (Cu), aluminum (Al), silver (Ag), gold (Au), tungsten (W), titanium (Ti), and a combination thereof.

The semiconductor package 1 may further include the external connection terminals 170 that is provided on first surfaces of the UBM layers 150. The external connection terminals 170 may be configured to connect the first redistribution layer 100 and an external device electrically and physically. According to an embodiment, the external connection terminals 170 may include, for example, a solder ball, a conductive bump, and a flip-chip connection structure having a grid array such as a pin grid array, a ball grid array, and a land grid array. The external connection terminals 170 may be electrically connected to the UBM layers 150 and may be electrically connected to the external device such as a module substrate, a system board, and a printed circuit board.

A glass interposer 200 may be provided on a second surface of the first redistribution layer 100 to electrically and/or physically connect the first redistribution layer 100 to the second redistribution layer 300 and the semiconductor chips. The glass interposer 200 may include a glass substrate 210 and through glass vias 220 vertically penetrating the glass substrate 210.

The interposer being made of glass may increase structural stiffness of overall package to reduce warpage of the semiconductor package. In addition, glass has tunable modulus and coefficient of thermal expansion (CTE) to enable larger form factor package, dimensional stability to improve feature scaling, lower loss for high-speed signaling between the semiconductor package 1 and external elements, and higher temperature stability which may overall improve the performance of the semiconductor package.

The through-glass vias 220 may be provided between the first redistribution layer 100 and the second redistribution layer 300, and provide an electrical connection path between the first redistribution layer 100 and the second redistribution layer 300. The plurality of through-glass vias 220 may include a conductive material including, for example, copper (Cu), aluminum (Al), silver (Ag), gold (Au), tungsten (W), titanium (Ti), and a combination thereof. The through-glass vias 220 may have a first surface and a second surface spaced apart from each other in the vertical direction (Z direction). The second surface of the through-glass vias 220 may be coplanar with the second surface of the glass substrate 210, and the first surface of the through-glass vias 220 may be coplanar with the first surface of the glass substrate 210. The through-glass vias 220 may be at least partially contact with at least one of the first vias 130 and first wiring patterns 120 exposed on a second surface of the uppermost first redistribution insulating layer 110. For example, the first surfaces of the through-glass vias 220 may be bonded and connected to at least one of the second surface of the first vias 130 and first wiring patterns 120.

Each of the through-glass vias 220 may have, for example, a cylindrical shape. The diameter of each of the through-glass vias 220 may be constant in the horizontal direction (X or Y direction). In another embodiment, the plurality of through-glass vias 220 may have tapered shapes having diameters in the horizontal direction (X or Y direction) that vary along the vertical direction (Z direction) depending on the manufacturing conditions.

The second redistribution layer 300 may be provided on the glass interposer 200. The second redistribution layer 300 may include one or more second redistribution insulating layers 310 and second vias 330. The second redistribution layer 300 may also include second wiring patterns connected to the second vias 330 to provide electrical connection between the glass interposer 200 and the semiconductor chips.

The second redistribution insulating layers 310 may be stacked in the vertical direction (Z direction) to provide insulation between the wiring patterns and vias that are not connected to each to each other. The second redistribution insulating layer 310 may include an insulating material, such as a photo-imageable dielectric (PID) resin prepared by combining epoxy resin and photoinitiators, and may further include photosensitive polyimide and/or inorganic fillers, not being limited thereto.

The second wiring patterns and the second vias 330 may be conductive and may be provided in the second redistribution insulating layer 310. The second wiring patterns may be provided to extend in the horizontal direction (X direction and/or Y direction) in the second redistribution insulating layer 310. The second vias 330 may penetrate one or more second redistribution insulating layer 310 in the vertical direction (Z direction), to thereby contact and be electrically connected with some of the second wiring patterns.

According to embodiments, at least some of the second wiring patterns may be integrally provided together with some of the second vias 330. For example, the second wiring patterns and the second vias 330, which are in contact with the second surface of the second wiring patterns, may be integrally formed as a single structure.

According to embodiments, the second vias 330 may have a tapered shape in which the horizontal widths of the second vias 330 decrease in the vertical direction (Z direction) away from the first semiconductor chip 10, the second semiconductor chip 20, and the third semiconductor chip 30 which may facilitate the manufacturing process.

The second wiring patterns and the second vias 330 may include, for example, metals such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and an alloy thereof but is not limited thereto.

The first semiconductor chip 10, the second semiconductor chip 20, and the third semiconductor chip 30 may be provided on the second surface of the second redistribution layer 300 and be electrically connected to structures external to the semiconductor package 1 though the second redistribution layer 300, the glass interposer 200, and the first redistribution layer 100. A first surface of the first semiconductor chip 10, a first surface of the second semiconductor chip 20, and a first surface of the third semiconductor chip 30 may be a surface including connection pads that electrically connect the first semiconductor chip 10, the second semiconductor chip 20, and the third semiconductor chip 30 to the second redistribution layer 300.

For example, the first semiconductor chip 10 and the second semiconductor chip 20 may be a high bandwidth memory (HBM) chip and a third semiconductor chip 30 may be a system-on-chip (SOC) or an application-specific integrated circuit (ASIC) chip. However, embodiments are not limited thereto. For example, the first semiconductor chip 10, the second semiconductor chip 20, and the third semiconductor chip 30 may be a memory chip such as a dynamic random access memory (DRAM) chip and a NAND chip, or a logic chip such as a central processing unit (CPU), a graphical processing unit (GPU), and a field FPGA chip, etc.

A mold layer 410 may be provided on the second surface of the second redistribution layer 300 and surround the first semiconductor chip 10, the second semiconductor chip 20, and the third semiconductor chip 30 to seal the semiconductor package 1 and protect the semiconductor package 1 from physical and chemical impacts. The mold layer 410 be an epoxy mold compound and may include, for example, epoxy mold resin including silicon fillers.

The semiconductor package 1 may further include a bridge chip 40. The bridge chip 40 may be provided embedded in the glass substrate 210. A second surface of the bridge chip 40 may be substantially coplanar with the second surface of the glass substrate 210. The bridge chip 40 may be provided as an electrical connection path between semiconductor chips. For example, a bridge chip 40 may provide an electrical connection path between the first semiconductor chip 10 and the third semiconductor chip 30 that are provided on the second redistribution layer 300, and an electrical connection path between the second semiconductor chip 20 and the third semiconductor chip 30 that are provided on the second redistribution layer 300. For example, the first semiconductor chip 10 and the third semiconductor chip 30 may be electrically connected to each other through a bridge circuit in the bridge chip 40. As shown in FIG. 1, each of the first semiconductor chip 10 and the third semiconductor chip 30 may overlap at least a portion of the bridge chip 40 in the vertical direction (Z direction). Similarly, for example, the second semiconductor chip 20 and the third semiconductor chip 30 may be electrically connected to each other through a bridge circuit in the bridge chip 40, and each of the second semiconductor chip 20 and the third semiconductor chip 30 may overlap at least a portion of the bridge chip 40 in the vertical direction (Z direction).

The bridge chip 40 may include a bridge substrate and the bridge circuit. The bridge chip 40 may be spaced apart from the first redistribution layer 100 but may be electrically and indirectly connected to the first redistribution layer 100 through the through-glass vias 220 and the second redistribution layer 300.

The second surface of the bridge chip 40 may include connection members 43 that electrically connect the bridge chip 40 to the second redistribution layer 300. The bridge chip 40 may include a semiconductor material, such silicon (Si). However, embodiments are not limited thereto. For example, the bridge chip 40 may include a semiconductor material as a Group IV semiconductor material, a Group III-V semiconductor material, a Group II-VI semiconductor material, and a combination thereof.

A connection member 43 may be provided between the bridge chip 40 and the second redistribution layer 300. The connection member 43 may contact the second wiring patterns and/or the second vias 330, and may electrically connect the second redistribution layer 300 to the bridge chip 40. For example, the connection member 43 may include a conductive pillar. For example, the connection member 43 may have a single cylindrical shape. Thus, the connection member 43 may have a constant diameter along the vertical direction (Z direction). In another embodiment, the connection member 43 may have a tapered shape in which the diameter changes along the vertical direction (Z direction) which may facilitate the manufacturing process. For example, the connection member 43 may include a conductive material such as copper (Cu), aluminum (Al), silver (Ag), gold (Au), tungsten (W), titanium (Ti), and a combination thereof.

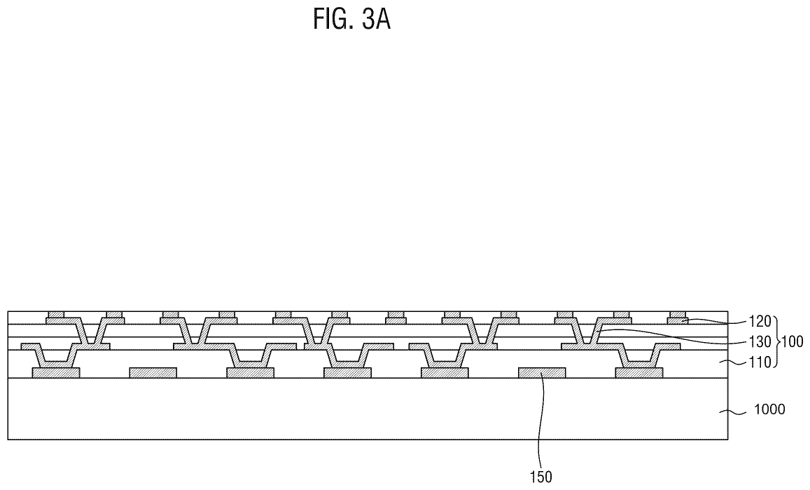

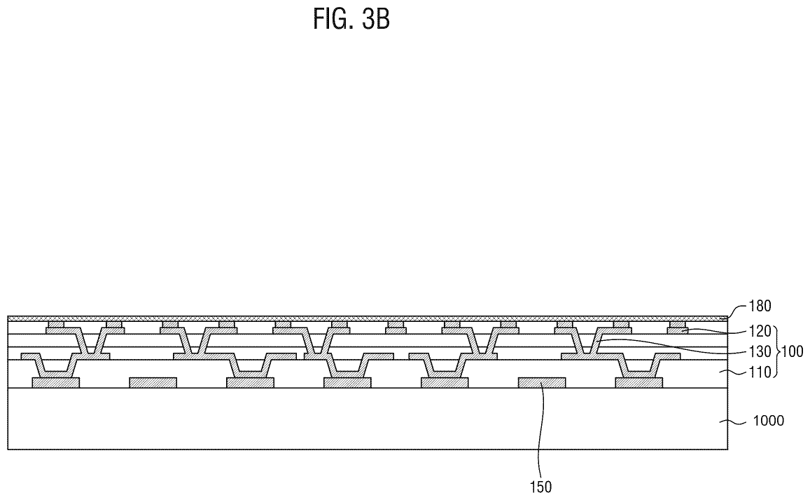

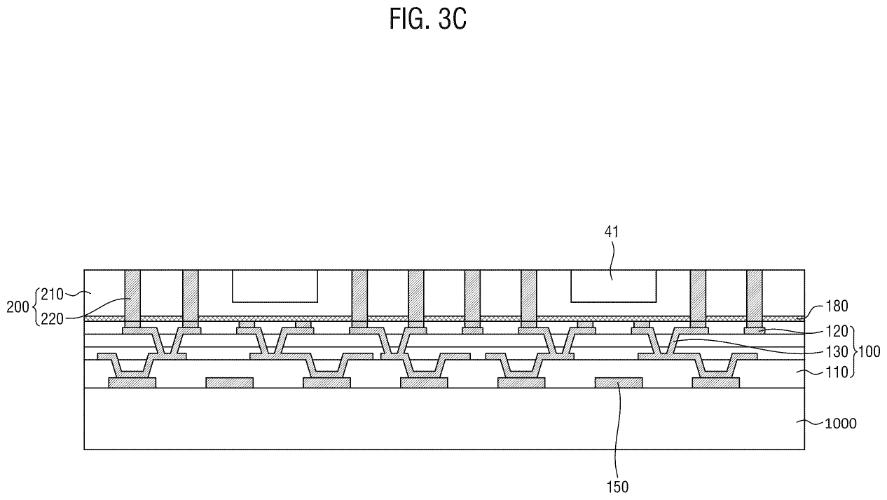

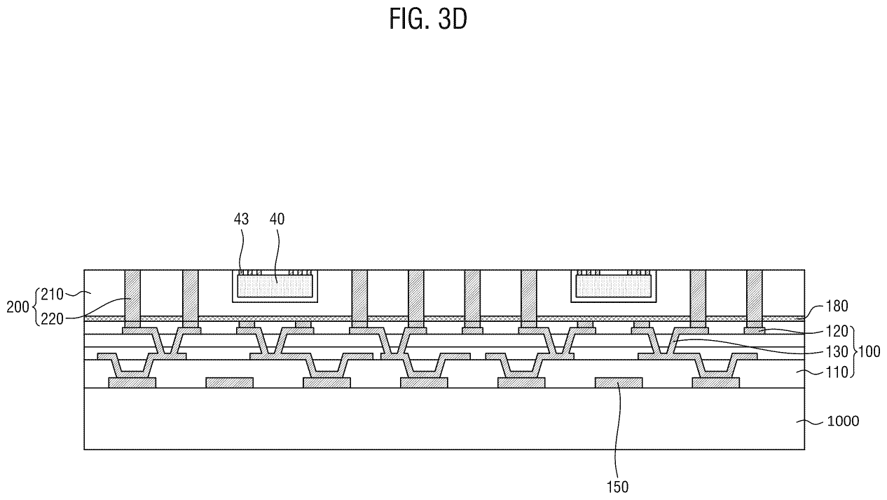

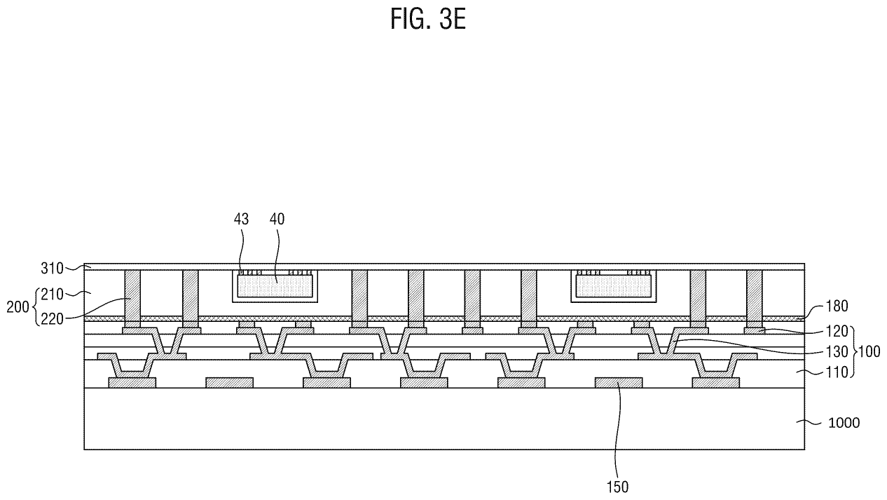

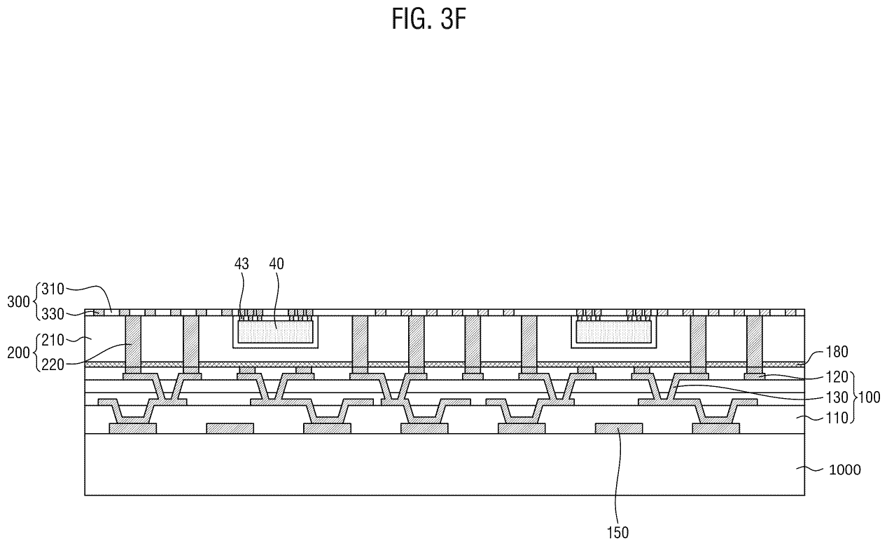

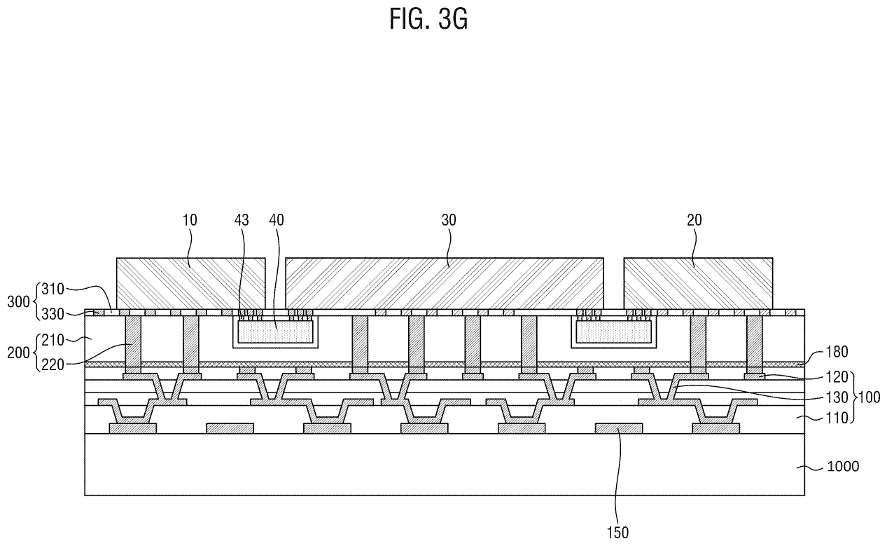

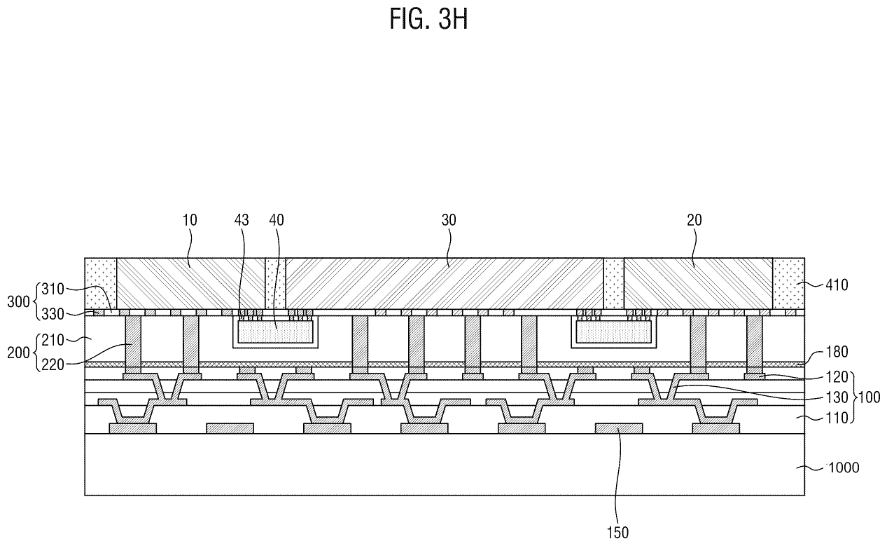

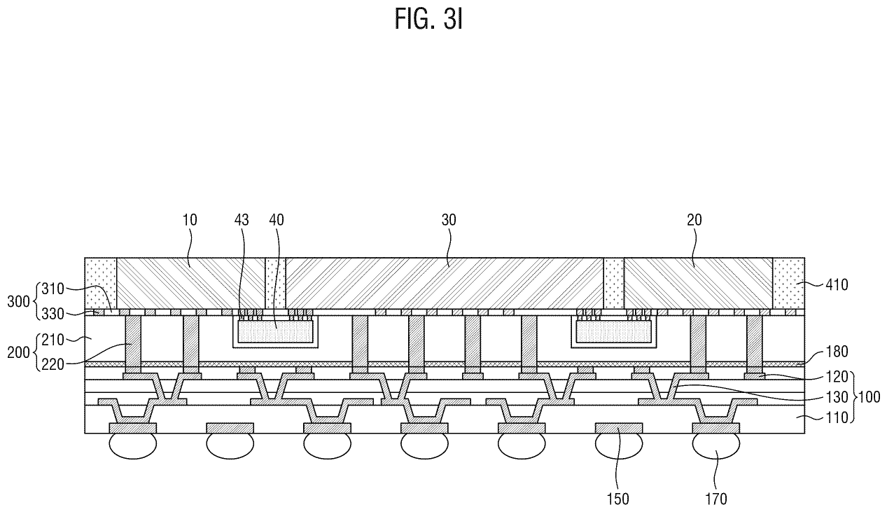

FIGS. 3A through 3I are cross-sectional views illustrating a method of manufacturing a semiconductor package according to one or more embodiments. Descriptions overlapping with previous drawings will be omitted for the sake of brevity and differences will mainly be described. The glass interposer and the first and second redistribution layers manufactured in the method described below may be or correspond to the glass interposer 200 and the first and second redistribution layers 100 and 300 shown in FIG. 1, and thus, the same reference numbers shown in FIG. 1 may be used herebelow.

Referring to FIG. 3A, a first redistribution layer 100 may be formed on a carrier substrate 1000. The first redistribution layer 100 may include first redistribution insulating layers 110, first wiring patterns 120, and first vias 130. The first redistribution insulating layers 110 may be stacked in the vertical direction (Z direction). The first redistribution insulating layer 110 may include an insulating material, such as a photo-imageable dielectric (PID) resin prepared by combining epoxy resin and photoinitiators, and may further include photosensitive polyimide and/or inorganic fillers, not being limited thereto.

The first wiring patterns 120 and the first vias 130 may be conductive and may be provided in the first redistribution insulating layer 110. The first wiring patterns 120 may be provided to extend in the horizontal direction (X direction and/or Y direction) in the first redistribution insulating layer 110. The first vias 130 may penetrate one or more first redistribution insulating layer 110 in the vertical direction (Z direction), to contact and be electrically connected with some of the first wiring patterns 120.

According to embodiments, at least some of the first wiring patterns 120 may be integrally provided together with some of the first vias 130. For example, the first wiring patterns 120 and the first vias 130, which are in contact with the second surface of the first wiring patterns 120, may be integrally formed a single structure.

According to embodiments, the first vias 130 may have a tapered shape in which the horizontal widths of the first vias 130 decrease in the vertical direction (Z direction) away from the first semiconductor chip 10 and the second semiconductor chip 20 which may facilitate the manufacturing process.

The first wiring patterns 120 and the first vias 130 may include, for example, metals such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and an alloy thereof but is not limited thereto.

According to embodiments, an under bump metallurgy (UBM) layers 150 may also be formed on the lowermost first redistribution insulating layer 110. The UBM layers 150 may be formed to be connected to at least one of the first wiring patterns 120 and the first vias 130. The UBM layers 150 may include a conductive material, for example, copper (Cu), aluminum (Al), silver (Ag), gold (Au), tungsten (W), titanium (Ti), and a combination thereof.

Referring to FIG. 3B, a photosensitive film 180 may be laminated on a second surface of the first redistribution layer 100.

Referring to FIG. 3C, a glass interposer 200 including a glass substrate 210 and through-glass vias 220 may be formed on a second surface of the photosensitive film 180. The glass interposer 200 may include cavities 41 on the second surface of the glass substrate. The glass substrate 210 may be prefabricated to include the through-glass vias and cavities 41 which may simplify the manufacturing process of the glass interposer.

The through-glass vias 220 may include a conductive material including, for example, copper (Cu), aluminum (Al), silver (Ag), gold (Au), tungsten (W), titanium (Ti), and a combination thereof.

The through-glass vias 220 may be formed to at least partially contact with at least one of the first vias 130 and first wiring patterns 120 exposed on a second surface of the uppermost first redistribution insulating layer 110. For example, the first surfaces of the through-glass vias 220 may be bonded and connected to at least one of the second surface of the first vias 130 and first wiring patterns 120.

Referring to FIG. 3D, bridge chips 40 may be embedded in the cavities 41 formed on the glass substrate 210. The bridge chips 40 may include a bridge substrate and the bridge circuit. Connection members 43 may be provided on second surfaces of the bridge chips 40. For example, the connection member 43 may include a conductive pillar. For example, the connection member 43 may have a single cylindrical shape. Thus, the connection member 43 may have a constant diameter along the vertical direction (Z direction). In another embodiment, the connection member 43 may have a tapered shape in which the diameter changes along the vertical direction (Z direction) which may facilitate the manufacturing process. For example, the connection member 43 may include a conductive material such as copper (Cu), aluminum (Al), silver (Ag), gold (Au), tungsten (W), titanium (Ti), and a combination thereof.

The glass substrate 210, the through-glass vias 220, and the connection members 43 may be grinded such that the second surfaces of the glass substrate 210, the through-glass vias 220, and the connection members 43 are substantially coplanar.

Referring to FIGS. 3E and 3F, a second redistribution layer 300 may be provided on the glass interposer 200. The second redistribution layer 300 may include one or more second redistribution insulating layers 310 and second vias 330. The second redistribution layer 300 may also include second wiring patterns. The second wiring patterns and/or the second vias 330 may be connected to the through-glass vias 220 and the connection members 43. The connection members 43 may electrically connect the second redistribution layer 300 to the bridge chip 40.

The second redistribution insulating layers 310 may be stacked in the vertical direction (Z direction). The second redistribution insulating layer 310 may include an insulating material, such as a photo-imageable dielectric (PID) resin prepared by combining epoxy resin and photoinitiators, and may further include photosensitive polyimide and/or inorganic fillers, not being limited thereto.

The second wiring patterns and the second vias 330 may be conductive and may be provided in the second redistribution insulating layer 310. The second wiring patterns may be provided to extend in the horizontal direction (X direction and/or Y direction) in the second redistribution insulating layer 310. The second vias 330 may penetrate one or more second redistribution insulating layer 310 in the vertical direction (Z direction), to thereby contact and be electrically connected with some of the second wiring patterns.

According to embodiments, at least some of the second wiring patterns may be integrally provided together with some of the second vias 330. For example, the second wiring patterns and the second vias 330, which are in contact with the second surface of the second wiring patterns, may be integrally formed as a single structure.

According to embodiments, the second vias 330 may have a tapered shape in which the horizontal widths of the second vias 330 decrease in the vertical direction (Z direction) away from the first semiconductor chip 10, the second semiconductor chip 20, and the third semiconductor chip 30 which may facilitate the manufacturing process.

The second wiring patterns and the second vias 330 may include, for example, metals such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and an alloy thereof but is not limited thereto.

Referring to FIG. 3G, a first semiconductor chip 10, a second semiconductor chip 20, and a third semiconductor chip 30 may be provided on the second surface of the second redistribution layer 300. A first surface of the first semiconductor chip 10, a first surface of the second semiconductor chip 20, and a first surface of the third semiconductor chip 30 may include connection pads that electrically connect the first semiconductor chip 10, the second semiconductor chip 20, and the third semiconductor chip 30 to the second redistribution layer 300.

Connection members 43 of a bridge chip 40 may be connected to the first semiconductor chip 10 and the third semiconductor chip 30 via the second wiring patterns and/or second vias, and provide an electrical connection path between the first semiconductor chip 10 and the third semiconductor chip 30. Connection members 43 of another bridge chip 40 may be connected to the second semiconductor chip 20 and the third semiconductor chip 30 via the second wiring patterns and/or second vias, and provide an electrical connection path between the second semiconductor chip 20 and the third semiconductor chip 30. Each of the first semiconductor chip 10 and the third semiconductor chip 30 may be formed to overlap at least a portion of the bridge chip 40 in the vertical direction (Z direction). Each of the second semiconductor chip 20 and the third semiconductor chip 30 may be formed to overlap at least a portion of the bridge chip 40 in the vertical direction (Z direction).

Referring to FIG. 3H, a mold layer 410 may be provided on the second surface of the second redistribution layer 300 and surround the first semiconductor chip 10, the second semiconductor chip 20, and the third semiconductor chip 30. The mold layer 410 be an epoxy mold compound and may include, for example, epoxy mold resin including silicon fillers.

Referring to FIG. 3I, the carrier substrate 1000 may be removed and external connection terminals 170 may be formed on the first surfaces of the UBM layers 150. The external connection terminals 170 may be configured to connect the first redistribution layer 100 and an external device electrically and physically. The external connection terminals 170 may include, for example, a solder ball, a conductive bump, and a flip-chip connection structure having a grid array such as a pin grid array, a ball grid array, and a land grid array. The external connection terminals 170 may be electrically connected to the UBM layers 150 and may be electrically connected to the external device such as a module substrate, a system board, and a printed circuit board.

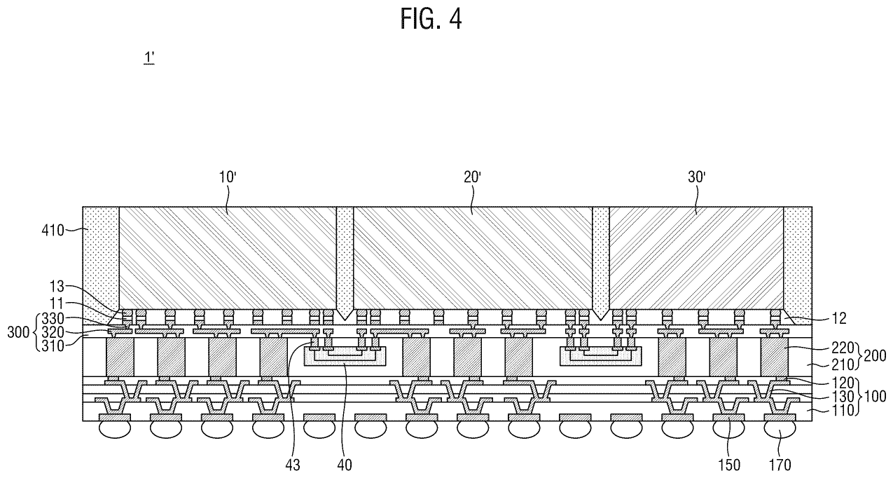

FIG. 4 illustrates a semiconductor package according to one or more other embodiments.

Referring to FIG. 4, a semiconductor package 1 may include a first semiconductor chip 10′, a second semiconductor chip 20′, a third semiconductor chip 30′, bridge chips 40, a first redistribution layer 100, a glass interposer 200, and a second redistribution layer 300.

The semiconductor package 1′ may include a package having a fan-out structure. A size of the first redistribution layer 100 and a size of the second redistribution layer 300 may be larger than a size of the first semiconductor chip 10′, the second semiconductor chip 20′, and the third semiconductor chip 30′. The size of the first redistribution layer 100 and the second redistribution layer 300 may be the same as a size of the semiconductor package 1′.

The first redistribution layer 100 may include first redistribution insulating layers 110, first wiring patterns 120, and first vias 130. The first redistribution insulating layers 110 may be stacked in the vertical direction (Z direction). The first redistribution insulating layer 110 may include an insulating material, such as a photo-imageable dielectric (PID) resin prepared by combining epoxy resin and photoinitiators, and may further include photosensitive polyimide and/or inorganic fillers, not being limited thereto.

The first wiring patterns 120 and the first vias 130 may be conductive and may be provided in the first redistribution insulating layer 110. The first wiring patterns 120 may be provided to extend in the horizontal direction (X direction and/or Y direction) in the first redistribution insulating layer 110. The first vias 130 may penetrate one or more first redistribution insulating layer 110 in the vertical direction (Z direction), to contact and be electrically connected with some of the first wiring patterns 120.

According to embodiments, at least some of the first wiring patterns 120 may be integrally provided together with some of the first vias 130. For example, the first wiring patterns 120 and the first vias 130, which are in contact with the second surface of the first wiring patterns 120, may be integrally formed as a single structure.

According to embodiments, the first vias 130 may have a tapered shape in which the horizontal widths of the first vias 130 decrease in the vertical direction (Z direction) away from the first semiconductor chip 10 and the second semiconductor chip 20 which may facilitate the manufacturing process.

The first wiring patterns 120 and the first vias 130 may include, for example, metals such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and an alloy thereof but is not limited thereto.

The semiconductor package 1′ may further include an under bump metallurgy (UBM) layers 150. The UBM layer 150 may include a copper layer, a nickel layer, and a copper-nickel-tin intermetallic compound layer between the copper layer and the nickel layer. The UBM layers 150 may be connected to at least one of the first wiring patterns 120 and the first vias 130, and may electrically connect the first redistribution layer 100 with other components of the semiconductor package 1′ such as an external connection terminals 170. In addition, the UBM layers 150 may prevent the external connection terminals 170 from cracking due to the thermal shock between the external connection terminals 170 and the first redistribution layer 100, to thereby improve the reliability of the semiconductor package 1′. The UBM layers 150 may include a conductive material, for example, copper (Cu), aluminum (Al), silver (Ag), gold (Au), tungsten (W), titanium (Ti), and a combination thereof.

The semiconductor package 1′ may further include the external connection terminals 170 that is provided on the first surface of the UBM layers 150. The external connection terminals 170 may be configured to connect the first redistribution layer 100 and an external device electrically and physically. According to an embodiment, the external connection terminals 170 may include, for example, a solder ball, a conductive bump, and a flip-chip connection structure having a grid array such as a pin grid array, a ball grid array, and a land grid array. The external connection terminals 170 may be electrically connected to the UBM layers 150 and may be electrically connected to the external device such as a module substrate, a system board, and a printed circuit board.

A glass interposer 200 may be provided on a second surface of the first redistribution layer 100. The glass interposer 200 may include a glass substrate 210 and through-glass vias 220 vertically penetrating the glass substrate 210.

The through-glass vias 220 may be provided between the first redistribution layer 100 and the second redistribution layer 300, and provide an electrical connection path between the first redistribution layer 100 and the second redistribution layer 300. The plurality of through-glass vias 220 may include a conductive material including, for example, copper (Cu), aluminum (Al), silver (Ag), gold (Au), tungsten (W), titanium (Ti), and a combination thereof.

The through-glass vias 220 may have a first surface and a second surface spaced apart from each other in the vertical direction (Z direction). The second surface of the through-glass vias 220 may be coplanar with the second surface of the glass substrate 210, and the first surface of the through-glass vias 220 may be coplanar with the first surface of the glass substrate 210. The through-glass vias 220 may at least partially contact with at least one of the first vias 130 and first wiring patterns 120 exposed on a second surface of the uppermost first redistribution insulating layer 110. For example, the first surfaces of the through-glass vias 220 may be bonded and connected to at least one of the second surface of the first vias 130 and first wiring patterns 120.

Each of the through-glass vias 220 may have, for example, a cylindrical shape. The diameter of each of the through-glass vias 220 may be constant in the horizontal direction (X or Y direction). In another embodiment, the plurality of through-glass vias 220 may have tapered shapes having diameters in the horizontal direction (X or Y direction) that vary along the vertical direction (Z direction) which may facilitate the manufacturing process.

The second redistribution layer 300 may be provided on the glass interposer 200. The second redistribution layer 300 may include one or more second redistribution insulating layers 310 and second vias 330. The second redistribution layer 300 may also include second wiring patterns.

The second redistribution insulating layers 310 may be stacked in the vertical direction (Z direction). The second redistribution insulating layer 310 may include an insulating material, such as a photo-imageable dielectric (PID) resin prepared by combining epoxy resin and photoinitiators, and may further include photosensitive polyimide and/or inorganic fillers, not being limited thereto.

The second wiring patterns and the second vias 330 may be conductive and may be provided in the second redistribution insulating layer 310. The second wiring patterns may be provided to extend in the horizontal direction (X direction and/or Y direction) in the second redistribution insulating layer 310. The second vias 330 may penetrate one or more second redistribution insulating layer 310 in the vertical direction (Z direction), to thereby contact and be electrically connected with some of the second wiring patterns.

According to embodiments, at least some of the second wiring patterns may be integrally provided together with some of the second vias 330. For example, the second wiring patterns and the second vias 330, which are in contact with the second surface of the second wiring patterns, may be integrally formed as a single structure.

According to embodiments, the second vias 330 may have a tapered shape in which the horizontal widths of the second vias 330 decrease in the vertical direction (Z direction) away from the first semiconductor chip 10, the second semiconductor chip 20, and the third semiconductor chip 30 which may facilitate the manufacturing process.

The second wiring patterns and the second vias 330 may include, for example, metals such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and an alloy thereof but is not limited thereto.

The first semiconductor chip 10′, the second semiconductor chip 20′, and the third semiconductor chip 30′ may be provided on the second surface of the second redistribution layer 300. A first surface of the first semiconductor chip 10′, a first surface of the second semiconductor chip 20′, and a first surface of the third semiconductor chip 30′ may include connection members 11 and connection pads 13 that electrically connect the first semiconductor chip 10′, the second semiconductor chip 20′, and the third semiconductor chip 30′ to the second redistribution layer 300. For example, the first semiconductor chip 10 may be electrically connected to the second redistribution layer 300 through the connection members 11 and connection pads 13. An underfill layer 12 may be provided adjacent to and to surround the connection members 11 and connection pads 13 between the first semiconductor chip 10 and the second redistribution layer 300. Connection members 11 and connection pads 13 may be provided between a first surface of the second semiconductor chip 20 and the second redistribution layer 300. The second semiconductor chip 20 may be electrically connected to the second redistribution layer 300 through the connection members 11 and connection pads 13. An underfill layer 12 may be provided adjacent to and to surround the connection members 11 between the second semiconductor chip 20 and the second redistribution layer 300. Connection members 11 and connection pads 13 may be provided between a first surface of the third semiconductor chip 30 and the second redistribution layer 300. The third semiconductor chip 30 may be electrically connected to the second redistribution layer 300 through the connection members 11 and connection pads 13. An underfill layer 12 may be provided adjacent to and to surround the connection members 11 between the third semiconductor chip 30 and the second redistribution layer 300. The underfill layer 12 may include a slant outer surface. The underfill layer 12 may include an epoxy resin or two or more silicon hybrid materials.

For example, the first semiconductor chip 10′ and the second semiconductor chip 20′ may be a logic chip and the third semiconductor chip 30′ may be high bandwidth memory (HBM) chip. However, embodiments are not limited thereto.

The semiconductor package 1′ may further include a bridge chip 40. The bridge chip 40 may be provided embedded in the glass substrate 210. A second surface of the bridge chip 40 may be substantially coplanar with the second surface of the glass substrate 210. The bridge chip 40 may be provided as an electrical connection path between semiconductor chips. For example, a bridge chip 40 may provide an electrical connection path between the first semiconductor chip 10′ and the second semiconductor chip 20′ that are provided on the second redistribution layer 300, and an electrical connection path between the second semiconductor chip 20′ and the third semiconductor chip 30′ that are provided on the second redistribution layer 300. For example, the first semiconductor chip 10′ and the second semiconductor chip 20′ may be electrically connected to each other through a bridge circuit in the bridge chip 40. As shown in FIG. 1, each of the first semiconductor chip 10′ and the second semiconductor chip 20′ may overlap at least a portion of the bridge chip 40 in the vertical direction (Z direction). Similarly, for example, the second semiconductor chip 20′ and the third semiconductor chip 30′ may be electrically connected to each other through a bridge circuit in the bridge chip 40, and each of the second semiconductor chip 20′ and the third semiconductor chip 30′ may overlap at least a portion of the bridge chip 40 in the vertical direction (Z direction).

The bridge chip 40 may include a bridge substrate and the bridge circuit. The bridge chip 40 may be spaced apart from the first redistribution layer 100 but may be electrically and indirectly connected to the first redistribution layer 100 through the through-glass vias 220 and the second redistribution layer 300.

The second surface of the bridge chip 40 may include connection members 43 that electrically connect the bridge chip 40 to the second redistribution layer 300. The bridge chip 40 may include a semiconductor material, such silicon (Si). However, embodiments are not limited thereto. For example, the bridge chip 40 may include a semiconductor material as a Group IV semiconductor material, a Group III-V semiconductor material, a Group II-VI semiconductor material, and a combination thereof.

A connection member 43 may be provided between the bridge chip 40 and the second redistribution layer 300. The connection member 43 may contact the second wiring patterns and/or the second vias 330, and may electrically connect the second redistribution layer 300 to the bridge chip 40. For example, the connection member 43 may include a conductive pillar. For example, the connection member 43 may have a single cylindrical shape. Thus, the connection member 43 may have a constant diameter along the vertical direction (Z direction). In another embodiment, the connection member 43 may have a tapered shape in which the diameter changes along the vertical direction (Z direction) which may facilitate the manufacturing process. For example, the connection member 43 may include a conductive material such as copper (Cu), aluminum (Al), silver (Ag), gold (Au), tungsten (W), titanium (Ti), and a combination thereof.

A mold layer 410 may be provided on the second surface of the second redistribution layer 300 and surround the first semiconductor chip 10, the second semiconductor chip 20, the third semiconductor chip 30, and the underfill layers 12 to seal the semiconductor package 1′ and protect the semiconductor package 1′ from physical and chemical impacts. The mold layer 410 be an epoxy mold compound and may include, for example, epoxy mold resin including silicon fillers.

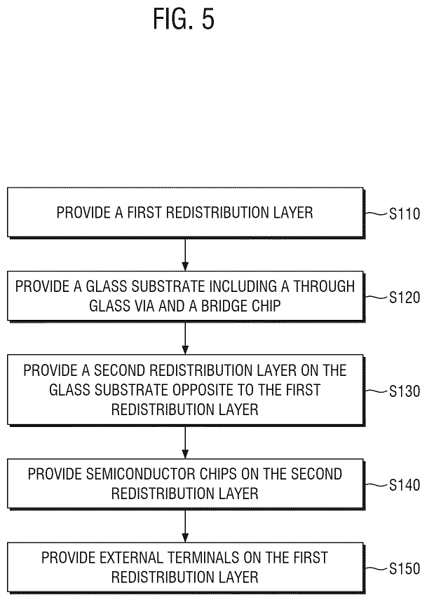

FIG. 5 illustrates a flowchart of manufacturing a semiconductor package according to one or more embodiments.

In operation S110, a first redistribution layer may be formed on a carrier substrate. A first redistribution insulating layer is provided on the carrier substrate, and first wiring patterns are formed on first redistribution insulating layer. By patterning the first redistribution insulating layer with a photoresist, first vias are formed to penetrate the first redistribution insulating layer, and may connect first wiring patterns provided at different vertical levels. Additional layers of the first redistribution insulating layers with first wiring patterns and first vias may be formed on a first surface of the first redistribution insulating layer. An under bump metallurgy (UBM) layers may be formed at the lowermost first redistribution insulating layer, and an external connection terminals may be formed on the UBM layers to connect the semiconductor package to an external device.

In operation S120, a glass interposer including a glass substrate and through-glass vias vertically penetrating the glass substrate is formed. The glass substrate may be prefabricated to include through-glass vias and cavities on the second surface of the glass substrate. However, embodiments are not limited thereto, and the glass substrate may be laser processed to form cavities on a second surface of the glass substrate, and a portion of the glass substrate may be wet etched or dry etched to form through glass tunnels penetrating the glass substrate. The through glass tunnels may be filled with metal material to form through-glass vias. The metal material may include a conductive material including, for example, copper (Cu), aluminum (Al), silver (Ag), gold (Au), tungsten (W), titanium (Ti), and a combination thereof, but embodiments are not limited thereto. Bridge chips may be formed in the cavities.

In operation S130, a second redistribution layer is formed on the second surface of the glass interposer. A second redistribution insulating layer is provided on the second surface of the glass substrate, and by patterning the second redistribution insulating layer with a photoresist, second wiring patterns are formed on second redistribution insulating layer. Second vias are formed to penetrate the second redistribution insulating layer, and may connect second wiring patterns provided at different vertical levels. Additional layers of the second redistribution insulating layers with second wiring patterns and second vias may be formed on a second surface of the second redistribution insulating layer.

At operation S140, semiconductor chips may be provided. For example, a semiconductor chips may be provided on the second surface of the second redistribution layer. Connection members may be formed to connect the semiconductor chip with second wiring patterns included in the second redistribution layer. Bridge chips may connect adjacent semiconductor chips through the second redistribution layer. An underfill layer may fill spaces between the connection members. The semiconductor chip may be a logic chip, an HBM chip, an SOC chip, etc. However, embodiments are not limited thereto.

In operation S150, external terminals may be formed to contact the UBM layers to connect the first redistribution layer 100 and an external device electrically and physically.

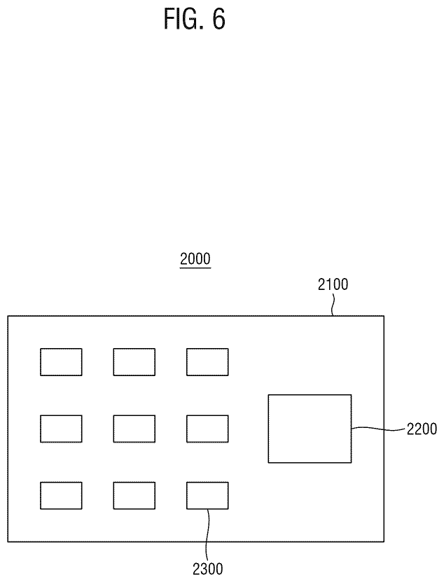

FIG. 6 illustrates a semiconductor package architecture that may incorporate the semiconductor packages according to one or more embodiments.

Referring to FIG. 6, a semiconductor package architecture 2000 according to an example embodiment may include a processor 2200 and semiconductor devices 2300 that are mounted on a substrate 2100. The processor 2200 and/or the semiconductor devices 2300 may include one or more of semiconductor packages described in the above embodiments.

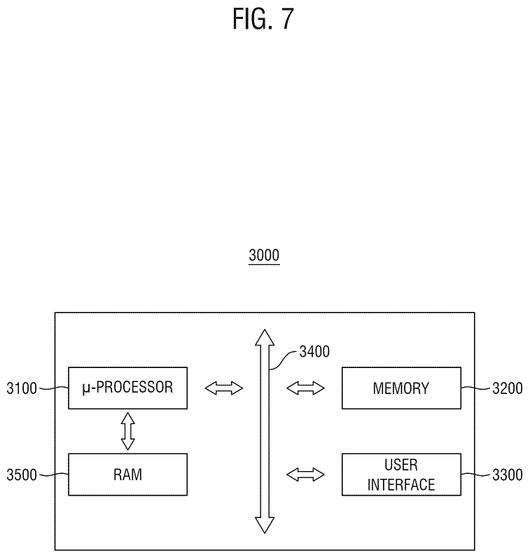

FIG. 7 illustrates a schematic block diagram of an electronic system according to one or more embodiments.

Referring to FIG. 7, an electronic system 3000 in accordance with an embodiment may include a microprocessor 3100, a memory 3200, and a user interface 3300 that perform data communication using a bus 3400. The microprocessor 3100 may include a central processing unit (CPU) or an application processor (AP). The electronic system 3000 may further include a random access memory (RAM) 3500 in direct communication with the microprocessor 3100. The microprocessor 3100 and/or the RAM 3500 may be implemented in a single module or package. The user interface 3300 may be used to input data to the electronic system 3000, or output data from the electronic system 3000. For example, the user interface 3300 may include a keyboard, a touch pad, a touch screen, a mouse, a scanner, a voice detector, a liquid crystal display (LCD), a micro light-emitting device (LED), an organic light-emitting diode (OLED) device, an active-matrix light-emitting diode (AMOLED) device, a printer, a lighting, or various other input/output devices without limitation. The memory 3200 may store operational codes of the microprocessor 3100, data processed by the microprocessor 3100, or data received from an external device. The memory 3200 may include a memory controller, a hard disk, or a solid state drive (SSD).

At least the microprocessor 3100, the memory 3200 and/or the RAM 3500 in the electronic system 3000 may include semiconductor packages as described in the above example embodiments.

It should be understood that embodiments described herein should be considered in a descriptive sense only and not for purposes of limitation. Descriptions of features or aspects within each embodiment should typically be considered as available for other similar features or aspects in other embodiments.

While embodiments have been described with reference to the figures, it will be understood by those of ordinary skill in the art that various changes in form and details may be made therein without departing from the spirit and scope as defined by the following claims.

What is claimed is:

1. A semiconductor package comprising:
a first redistribution layer;
a second redistribution layer;
a glass substrate between the first redistribution layer and the second redistribution layer, the glass substrate comprising a through-glass via configured to connect the first redistribution layer and the second redistribution layer;
a first semiconductor chip and a second semiconductor chip on a second surface of the second redistribution layer; and
a bridge chip included in the glass substrate and configured to connect the first semiconductor chip and the second semiconductor chip.

2. The semiconductor package according to claim 1, wherein the first redistribution layer comprises a first redistribution insulating layer, a first wiring pattern, and a first via connected to the first wiring pattern, and
wherein the second redistribution layer comprises a second redistribution insulating layer, a second wiring pattern, and a second via connected to the second wiring pattern.

3. The semiconductor package according to claim 2, wherein the bridge chip is provided to face the second redistribution layer and is configured to be electrically connected to the second redistribution layer.

4. The semiconductor package according to claim 2, further comprising a first connection member on a second surface of the bridge chip,
wherein the first connection member is connected to at least one of the second wiring pattern and second via and configured to connect the bridge chip to the first semiconductor chip and the second semiconductor chip.

5. The semiconductor package according to claim 4, wherein the bridge chip electrically connects the first semiconductor chip and the second semiconductor chip through the second redistribution layer.

6. The semiconductor package according to claim 1, further comprising a mold layer on the second surface of the second redistribution layer and surrounding the first semiconductor chip and the second semiconductor chip, the mold layer being configured to seal the first semiconductor chip and the second semiconductor chip.

7. The semiconductor package of claim 1, wherein the bridge chip is spaced apart for the through-glass via.

8. The semiconductor package of claim 2, wherein the first redistribution layer further comprises an under bump metallurgy (UBM) layer, and
wherein the semiconductor package further comprises an external terminal on the UBM layer, the external terminal being configured to connect the semiconductor package to a structure external to the semiconductor package.

9. The semiconductor package of claim 1, wherein the bridge chip overlaps a portion of the first semiconductor chip and a portion of the second semiconductor chip in a vertical direction.

10. The semiconductor package of claim 1, further comprising a second connection member and a connection pad between the first and second semiconductor chips and the second redistribution layer.

11. A method of manufacturing a semiconductor package, the method comprising:
providing a first redistribution layer comprising a first redistribution insulating layer, a first wiring pattern, and a first via connected to the first wiring pattern on a carrier substrate;
providing a glass substrate comprising a through-glass via on the first redistribution layer, the glass substrate being configured to be electrically connected to the first redistribution layer;
providing a bridge chip;
providing a second redistribution layer comprising a second redistribution insulating layer, a second wiring pattern, and a second via connected to the second wiring pattern on the glass substrate and configured to be electrically connected to the glass substrate; and
providing a first semiconductor chip and a second semiconductor chip on the second redistribution layer,
wherein the bridge chip is configured to electrically connect the first semiconductor chip and the second semiconductor chip.

12. The method of claim 11, further comprising providing a first connection member on a second surface of the bridge chip to be connected to at least one of the second wiring pattern and second via.

13. The method of claim 11, wherein the bridge chip is provided to overlap a portion of the first semiconductor chip and a portion of the second semiconductor chip in a vertical direction.

14. A semiconductor package comprising:
a first redistribution layer comprising a first redistribution insulating layer, a first wiring pattern, and a first via connected to the first wiring pattern;
a second redistribution layer comprising second redistribution insulating layer, a second wiring pattern, and a second via connected to the second wiring pattern;
a glass substrate between the first redistribution layer and the second redistribution layer, the glass substrate comprising a through-glass via configured to connect the first redistribution layer and the second redistribution layer;
a first semiconductor chip and a second semiconductor chip on a second surface of the second redistribution layer;
a bridge chip included in the glass substrate and electrically connecting the first semiconductor chip and the second semiconductor chip, the bridge chip being configured to electrically connect the first semiconductor chip and the second semiconductor chip; and
an external terminal on the first redistribution layer, the external terminal being configured to connect the semiconductor package to a structure external to the semiconductor package.

15. The semiconductor package according to claim 14, wherein the bridge chip is provided to face the second redistribution layer and is configured to be electrically connected to the second redistribution layer.

16. The semiconductor package according to claim 14, further comprising a first connection member on a second surface of the bridge chip,
wherein the first connection member is connected to at least one of the second wiring pattern and the second via and configured to connect the bridge chip to the first semiconductor chip and the second semiconductor chip.

17. The semiconductor package according to claim 14, further comprising a mold layer on the second surface of the second redistribution layer and surrounding the first semiconductor chip and the second semiconductor chip, the mold layer being configured to seal the first semiconductor chip and the second semiconductor chip.

18. The semiconductor package of claim 14, wherein the bridge chip is spaced apart for the through-glass via.

19. The semiconductor package of claim 14, wherein the first redistribution layer further comprises an under bump metallurgy (UBM) layer, and
wherein the external terminal is on the UBM layer.

20. The semiconductor package of claim 14, wherein the bridge chip overlaps a portion of the first semiconductor chip and a portion of the second semiconductor chip in a vertical direction.
